(19) United States
(12) Patent Application Publication
(10) Pub. No.: US 2012/0193552 A1
(43) Pub. Date: Aug. 2, 2012

(54) FLUORESCENCE LIFETIME IMAGING

(76) Inventors: Huw Summers, Swansea (GB); Rachel Errington, Vale of Glamorgan (GB); Paul Rees, Swansea (GB)

(21) Appl. No.: 13/262,230

(22) PCT Filed: Mar. 30, 2010
(86) PCT No.: PCT/GB10/50539

§ 371 Date: Apr. 13, 2012

(30) Foreign Application Priority Data
Apr. 1, 2009 (GB) 0905690.4

(51) Int. Cl. G01N 21/64; H01L 27/146

(52) U.S. Cl. 250/459.1; 250/458.1; 250/214 R; 250/208.1

(57) ABSTRACT

A method of measuring fluorescence from a location, the method comprising applying to the location a first fluorescence excitation signal having a first duty cycle, accumulating as a first result fluorescence that emanates from the location in response to the first excitation signal, applying to the location a second fluorescence excitation signal having a second duty cycle, accumulating as a second result fluorescence that emanates from the location in response to the second excitation signal, and comparing the first and second results to provide a comparison result for the location. The invention also relates to apparatus for performing the method.

### FIELD

The invention relates to the field of assessing sample material based on the fluorescence lifetime of fluorescent material in the sample material.

### BACKGROUND

Fluorescence lifetime imaging (FLIM) is a well known microscopy technique. There are two main types of FLIM. These are time domain FLIM and frequency domain FLIM.

In time domain FLIM, it is typically the case that an impulse of laser energy is used to excite fluorescence in a microscopy sample. A high sample rate detector is then used to sample the resulting fluorescence and the lifetime is extracted from the exponential decay trend that should be manifest in the captured sample sequence. The sample rate of the detector must typically be in the 10⁹ Hertz range, and such components with such performance are relatively costly.

In frequency domain FLIM, it is typically the case that a sinusoidally modulated light beam is used to excite fluorescence in a microscopy sample. As in time domain FLIM, a relatively fast detector is required to sample the fluorescence, which should exhibit a sinusoidal modulation offset in phase relative to, but of frequency equal to, the modulation applied to the stimulating laser. Furthermore, relatively high clock rate electronics is needed to synchronise the modulation of the stimulating laser with the waveform of the detected fluorescence.

### BRIEF DESCRIPTION OF THE INVENTION

The invention is defined by the appended claims, to which reference should now be made.

### BRIEF DESCRIPTION OF THE DRAWINGS

By way of example only, certain embodiments of the invention will be described with reference to the accompanying drawings in which:

FIG. 1 is a block diagram schematically illustrating a fluorescence lifetime imaging microscope (FLIM); and

FIG. 2 is a chart plotting variation in a parameter calculated from results produced by the microscope of FIG. 1.

### DETAILED DESCRIPTION

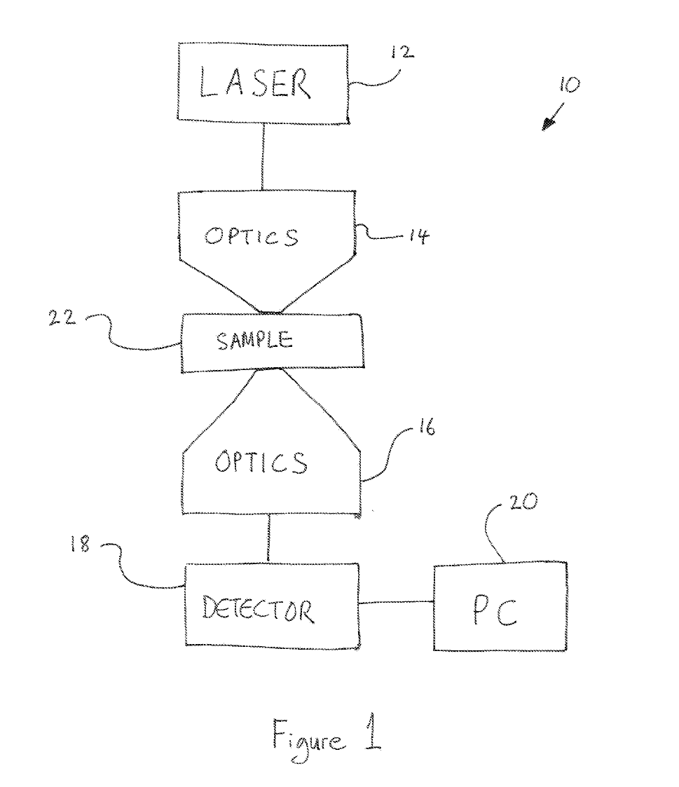

FIG. 1 shows an optical system 10 comprising a high energy, pulsed laser 12, an input optical system 14, an output optical system 16, a fluorescence detector 18 and a computer 20. As shown, a sample 22 is installed in the system 10. In the present example, the sample is a slide on which is fixed a group of cells that have been stained with fluorophores in the form of fluorescent nanocrystals (quantum dots) that have been introduced to the sample 22. The input optical system 14 serves to channel light from the laser 12 into the sample 22 where it stimulates the fluorophores. Fluorescence emitted by the fluorophores is then collected by the output optical system 16 and registered by the detector 18. In this example, the detector 18 is a charge coupled device (CCD) camera. The digital signals produced by the detector are supplied to the computer 20 for processing.

The laser 12 emits pulses of radiation to excite the fluorophores. The duty cycle of the radiation emitted by the laser 12 is characterised by a pulse of picosecond scale duration at a repetition rate that can be varied up to hundreds of MHz.

In this example, the laser 12 illuminates an area of the slide that is broad in comparison with the cells under examination and the detector 18 captures images of the fluorescence from the illuminated area. Of course, in other embodiments, the input optical system 14 provides point-like illumination of the sample 22 and includes a scanning arrangement to allow the illumination point to be moved over the sample and in such cases the detector 18 typically employs a relatively simple photodetector rather than a more complicated CCD camera.

The computer 20 processes the output of each CCD to produce a corresponding pixel for an image of the illuminated area of the sample 22. As a precursor to describing that processing, the physics of the fluorescence excitation and decay of the fluorophores will now be briefly discussed.

When a fluorophore absorbs light from a laser pulse, it moves from a ground state to an excited state and, some time later, decays back to the ground state emitting fluorescence in the process. Therefore, after excitation by a laser pulse, the fluorescence emitted by the sample 22 will decay and can be described using an exponential function characterised by a fluorescence lifetime of τ. That is to say, at time t after an excitation pulse, the intensity of the fluorescence will be proportional to

$${e}^{- \frac{t}{τ}} .$$

Assume now that the pulses of the laser 12 have a repetition frequency f such that the duration between the starts of two consecutive pulses is T. If it is the case that T is less than τ, then the majority of the fluorophores do not have time to decay from the excited state to the ground state with the result that there is a permanent subpopulation of fluorophores in the excited state. In this situation, there will be saturation of the overall absorption of the pulsed laser radiation by the fluorophores, leading to reduced efficiency in the excitation of the fluorophores and a reduced fluorescence integrated over the duty cycle of T of the laser.

Mathematically, E, the energy of the fluorescence light that is incident upon a CCD of the detector 18 over the course of one duty cycle of the laser 12, is:

$$E ∝ \frac{κ}{T} \cdot \frac{( {e}^{α P} - 1 )}{( {e}^{α P} - {e}^{- \frac{T}{τ}} )} \cdot ( 1 - {e}^{- \frac{T}{τ}} )$$

where κ is the Boltzmann constant and αP is related to the number of excitation events per cycle. The output value from a CCD of the camera will be proportional to the accumulation of (or in other words proportional to the integral of) E over the duration of the sampling time of the camera.

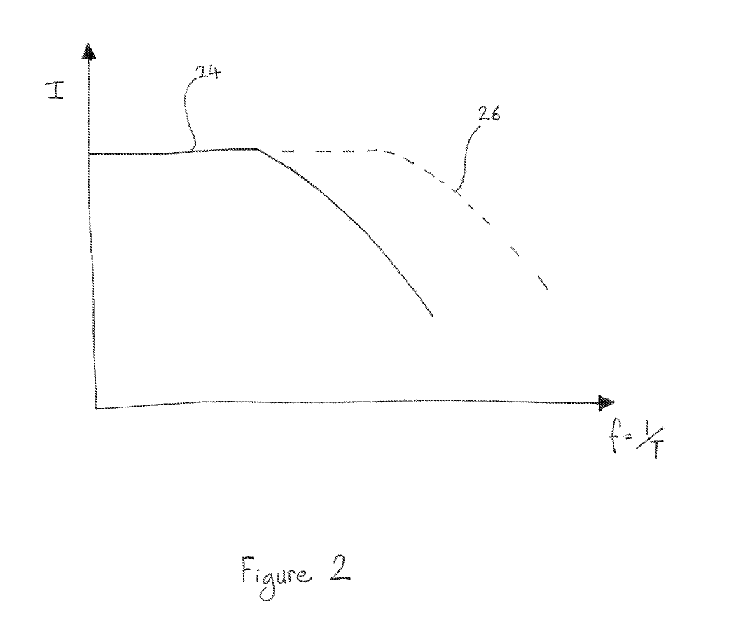

FIG. 2 demonstrates how E varies with T and plots E versus 1/T (i.e. against f) when the fluorophores are excited by the laser 12. The solid line 24 represents the result where the fluorophore lifetime is τ₁ and the dashed line 26 represents the result where the flurophore lifetime is τ₂, where τ₁>τ₂. It will be apparent that, for both τ₁ and τ₂, E is steady at low f and then falls off as f increases, the fall off occurring sooner (i.e. at lower f) in the τ₁ case. In each case, the departure from the plateau commences when T becomes less than approximately twice the fluorophore lifetime.

The computer 20 captures first and second images of the sample 22 at respective laser pulse frequencies f₁ and f₂. For the j^{th} CCD within the camera, its output value for the first image (i.e. when the laser pulse frequency is f₁) is S_{1,j} and its output value for second image (i.e. when the laser pulse frequency is f₂) is S_{2,j}. The computer 20 calculates a ratio R for the j^{th} CCD which is defined as:

$${R}_{j} = \frac{{f}_{2}}{{f}_{1}} \cdot \frac{{S}_{1 , j}}{{S}_{2 , j}}$$

This is a ratio of the values S_{1,j} and S_{2,j} after normalisation to account for the difference in their excitation pulse frequencies f₁ and f₂. If this scaling were not performed, the ratio would be biased by the fact that S_{2,j} is a measurement that is an integral over f₂/f₁ more excitation cycles than S_{1,j}. The frequencies f₁ and f₂ are chosen such that E for the fluorophore being imaged is markedly different at f₁ and f₂ so that a contrast picture can be created. Clearly, contrast would be largely unobtainable if both f₁ and f₂ where within the plateau of the E function illustrated in FIG. 2. Typically then, 1/f₁ is set greater than twice the fluorophore lifetime and 1/f₂ is set to be less than the fluorophore lifetime.

The computer 20 calculates the value R for each CCD of the camera of the detector 18. This set of R values is then plotted as an array of pixels making up an image of the sample.

Thus, a contrast image of the sample can be obtained using a CCD camera which has a slow response (relative, that is, to the electronics required in time domain FLIM and frequency domain FLIM), with each CCD of the camera generating an output value which is in effect an integral of the received fluorescence light over many duty cycles of the laser 12.

In an alternative embodiment, a pulsed LED is used in place of the laser 12.

1.-8. (canceled)

9. A method of measuring fluorescence from a location, the method comprising the steps of:
applying to the location a first fluorescence excitation signal having a first duty cycle;
accumulating as a first result fluorescence that emanates from the location in response to the first excitation signal;
applying to the location a second fluorescence excitation signal having a second duty cycle;
accumulating as a second result fluorescence that emanates from the location in response to the second excitation signal; and
comparing the first and second results to provide a comparison result for the location.

10. The method according to claim 9, wherein the comparison of the first and second results is a ratiometric comparison.

11. The method according to claim 10, wherein comparing the first and second results comprises taking a ratio of the first and second results with weights reflecting the length of their respective duty cycles.

12. The method according to claim 9, wherein comparing the first and second results comprises taking a ratio of the first and second results with weights reflecting the length of their respective duty cycles.

13. A method of forming an image of a sample, the method comprising the steps of:
determining a respective comparison result for each of a number of locations in the sample; and
plotting the comparison results as image pixels thereby producing an image of at least part of the sample;
wherein the step of determining comprises:
applying to the location a first fluorescence excitation signal having a first duty cycle;
accumulating as a first result fluorescence that emanates from the location in response to the first excitation signal;
applying to the location a second fluorescence excitation signal having a second duty cycle;
accumulating as a second result fluorescence that emanates from the location in response to the second excitation signal; and
comparing the first and second results to provide a comparison result for the location.

14. An apparatus for measuring fluorescence from a location, the apparatus comprising:
a laser arranged to apply to the location a first fluorescence excitation signal having a first duty cycle and a second fluorescence excitation signal having a second duty cycle; and
a computer arranged to accumulate as a first result fluorescence that emanates from the location in response to the first excitation signal, and as a second result fluorescence that emanates from the location in response to the second excitation signal, and further arranged to compare the first and second results to provide a comparison result for the location.

15. The apparatus according to claim 14, wherein the computer is arranged to make a ratiometric comparison of the first and second results.

16. The apparatus according to claim 15, wherein the computer is arranged to calculate a ratio of the first and second results with weights reflecting the length of their respective duty cycles.

17. The apparatus according to claim 14, wherein the computer is arranged to calculate a ratio of the first and second results with weights reflecting the length of their respective duty cycles.

18. The apparatus according to claim 14, wherein the computer is further arranged to plot the comparison result as an image pixel in an image of at least part of the sample.
